(19) United States
(12) Patent Application Publication
(10) Pub. No.: US 2026/0354035 A1
(43) Pub. Date: Nov. 5, 2026

(54) MAGNETIC MEMORY DEVICE INCLUDING SHIELDING STRUCTURE

(71) Applicant: SAMSUNG ELECTRONICS CO., LTD., Suwon-si (KR)

(72) Inventors: Jaehoon Kim, Suwon-si (KR); Myoungkwan Chae, Suwon-si (KR); Jeongheon Park, Suwon-si (KR)

(73) Assignee: SAMSUNG ELECTRONICS CO., LTD., Suwon-si (KR)

(21) Appl. No.: 19/644,241

(22) Filed: Apr. 10, 2026

(30) Foreign Application Priority Data
Apr. 30, 2025 (KR) 10-2025-0057366

(51) Int. Cl. H10N 50/85; H10N 50/10; G11C 11/16

(52) U.S. Cl. CPC H10N 50/85; H10N 50/10; G11C 11/161

(57) ABSTRACT

A magnetic memory device may include: a substrate; magnetic memory elements spaced apart from each other on the substrate, the magnetic memory elements comprising a magnetic tunnel junction pattern; and a shielding structure surrounding the magnetic memory elements in horizontal directions. The shielding structure may include: a plate portion between the magnetic memory elements; and a protrusion protruding from the plate portion, and surrounding a magnetic memory element from among the magnetic memory elements in the horizontal directions.

### CROSS-REFERENCE TO RELATED APPLICATION

This application claims benefit of priority to Korean Patent Application No. 10-2025-0057366, filed on Apr. 30, 2025 in the Korean Intellectual Property Office, the disclosure of which is incorporated herein by reference in its entirety.

### BACKGROUND

### 1. Field

Some embodiments of the present disclosure relate to a magnetic memory device.

### 2. Description of Background Art

A magnetic memory device may be a non-volatile memory device which reads and writes data using a magnetic tunnel junction pattern including two magnetic materials and an insulating layer interposed therebetween. A resistance value of the magnetic tunnel junction pattern may vary depending on a magnetization direction of the two magnetic materials, and data may be programmed or erased by utilizing such a difference in resistance values. A magnetic memory device using a spin transfer torque (STT) phenomenon uses a method in which a magnetization direction of a magnetic material changes due to a spin transfer of electrons, when a current with spin polarization in one direction is passed.

### SUMMARY

According to some embodiments of the present disclosure, a magnetic memory device having improved shielding characteristics against an external magnetic field may be provided.

According to some embodiments of the present disclosure, a magnetic memory device may include: a substrate; magnetic memory elements spaced apart from each other on the substrate, the magnetic memory elements comprising a magnetic tunnel junction pattern; and a shielding structure surrounding the magnetic memory elements in horizontal directions. The shielding structure may include: a plate portion between the magnetic memory elements; and a protrusion protruding from the plate portion, and surrounding a magnetic memory element from among the magnetic memory elements in the horizontal directions.

According to some embodiments of the present disclosure, a magnetic memory device may include: a substrate; selection elements on the substrate; a lower interlayer insulating layer on the selection elements; magnetic memory elements spaced apart from each other on the lower interlayer insulating layer, connected to the selection elements, and comprising a magnetic tunnel junction pattern; and a shielding structure surrounding the magnetic memory elements in horizontal directions. The shielding structure may include: a plate portion extending in a first direction, from among the horizontal directions, the first direction being parallel to an upper surface of the lower interlayer insulating layer; and a protrusion extending from the plate portion in a second direction, crossing the first direction, the protrusion surrounding a side surface of a magnetic memory element from among the magnetic memory elements in the horizontal directions.

According to some embodiments of the present disclosure, a magnetic memory device may include: a substrate; selection elements on the substrate; a lower interlayer insulating layer on the selection elements; magnetic memory elements spaced apart from each other on the lower interlayer insulating layer, connected to the selection elements, and comprising a magnetic tunnel junction pattern; a first insulating layer on an upper surface of the lower interlayer insulating layer and on the magnetic memory elements, the first insulating layer comprising a first thickness; and a shielding structure extending on the first insulating layer in a first direction, and on a side surface of the magnetic memory elements in a second direction that crosses the first direction. Upper surfaces of the magnetic memory elements may be exposed from the shielding structure.

### BRIEF DESCRIPTION OF DRAWINGS

The above and other aspects, features, and advantages of embodiments of the present disclosure will be more clearly understood from the following detailed description, taken in conjunction with the accompanying drawings:

FIG. 1 is a circuit diagram illustrating a cell array of a magnetic memory device according to an example embodiment of the present disclosure;

FIG. 2 is a plan view of a magnetic memory device according to an example embodiment of the present disclosure;

FIG. 3 is an exploded perspective view of a magnetic memory device according to an example embodiment of the present disclosure;

FIG. 4 is a cross-sectional view of a magnetic memory device according to an example embodiment of the present disclosure, illustrating a cross-section taken along a line I-I’ of FIG. 2;

FIG. 5 is an enlarged view of a portion of the magnetic memory device of FIG. 4;

FIG. 6 is a diagram illustrating a magnetic field line passing through the magnetic memory element of FIG. 5;

FIG. 7, FIG. 8, FIG. 9, FIG. 10, FIG. 11, FIG. 12, and FIG. 13 are diagrams illustrating a magnetic memory device according to example embodiments of the present disclosure;

FIG. 14A, FIG. 14B, FIG. 14C, FIG. 14D, FIG. 14E, FIG. 14F, and FIG. 14G are diagrams illustrating a method of manufacturing a magnetic memory device according to an example embodiment of the present disclosure step-by-step, and are cross-sectional views corresponding to FIG. 4; and

FIG. 15 and FIG. 16 are block diagrams illustrating an electronic device including a magnetic memory device according to an example embodiment of the present disclosure.

### DETAILED DESCRIPTION

Hereinafter, non-limiting example embodiments of the present disclosure will be described with reference to the attached drawings.

The example embodiments of the present disclosure may be modified in various other forms or various embodiments may be combined, and the scope of the present disclosure is not limited to the example embodiments described below. In addition, the example embodiments of the present disclosure are provided to more completely explain the present disclosure to those with ordinary skill in the relevant technical field. Accordingly, the shapes and sizes of elements in the drawings may be exaggerated for clearer explanation, and elements indicated by the same symbols in the drawings may be the same elements.

The example embodiments of the present disclosure are not limited to the specific shapes shown, but also include variations in shapes produced according to the manufacturing process. For example, the etched region shown at a right angle may be rounded or have a shape with a predetermined curvature. Accordingly, the regions illustrated in the drawings have schematic properties, and the shapes of the regions illustrated in the drawings are intended to illustrate specific forms of regions of the device and are not intended to limit the scope of the present disclosure.

Unless otherwise specifically stated, in this specification, the terms “on,” “upper surface,” “below,” “lower surface,” “upward,” “downward,” “lateral surface,” “high,” “low,” and the like, are based on the drawings, and may actually vary depending on a direction in which a light emitting element is disposed. In addition, “on” and “under” include both those formed “directly” or “indirectly” on nor under through other components.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

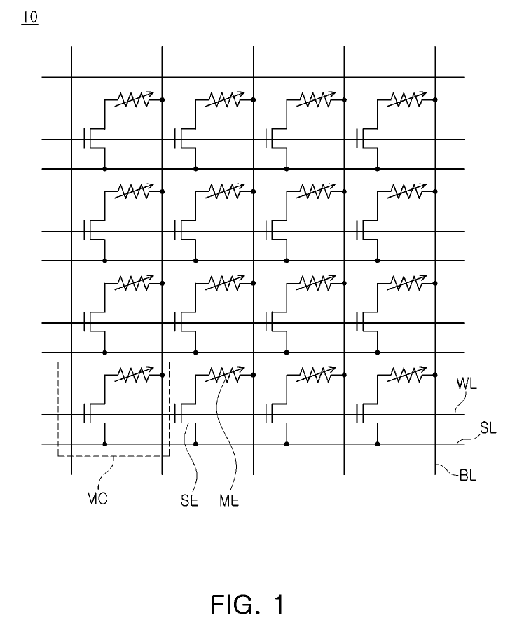

FIG. 1 is a circuit diagram illustrating a cell array of a magnetic memory device according to an example embodiment of the present disclosure.

Referring to FIG. 1, the cell array of the magnetic memory device 10may include unit cells MC of the magnetic memory device disposed in a matrix form. The unit cells MC of the magnetic memory device include a select element SE and a magnetic memory element ME. The unit cells MC of the magnetic memory device may be electrically connected to word lines WL and bit lines BL.

In addition, when the selection element SE is a transistor as illustrated in FIG. 1, a source line SL electrically connected to a source region of the selection element SE may be further included. The word line WL and the bit line BL may be arranged two-dimensionally at a certain angle such as, for example, vertically. In addition, the word line WL and the source line SL may be arranged at a certain angle such as, for example, parallel to each other.

The magnetic memory element ME may include a magnetic tunnel junction (MTJ). The magnetic memory element ME may perform a memory function as a variable resistor in which resistance between two electrodes disposed at opposite ends of a magnetic tunnel junction changes by using a spin torque transfer (STT) phenomenon in which a magnetization direction of a magnetic material changes depending on an input current.

The selection element SE may be configured to selectively control a flow of charges through a magnetic tunnel junction. For example, the selection element SE may be one from among a diode, a PNP bipolar transistor, an NPN bipolar transistor, an N-channel metal oxide semiconductor (NMOS) field effect transistor, and a P-channel metal oxide semiconductor (PMOS) field effect transistor.

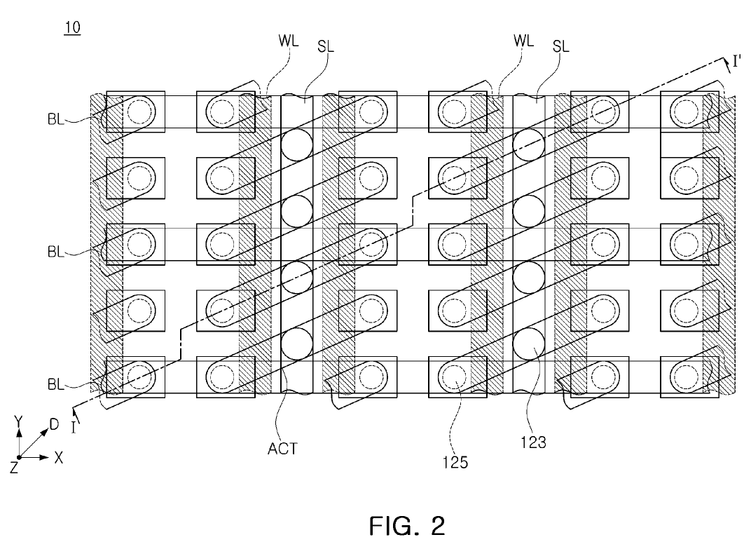

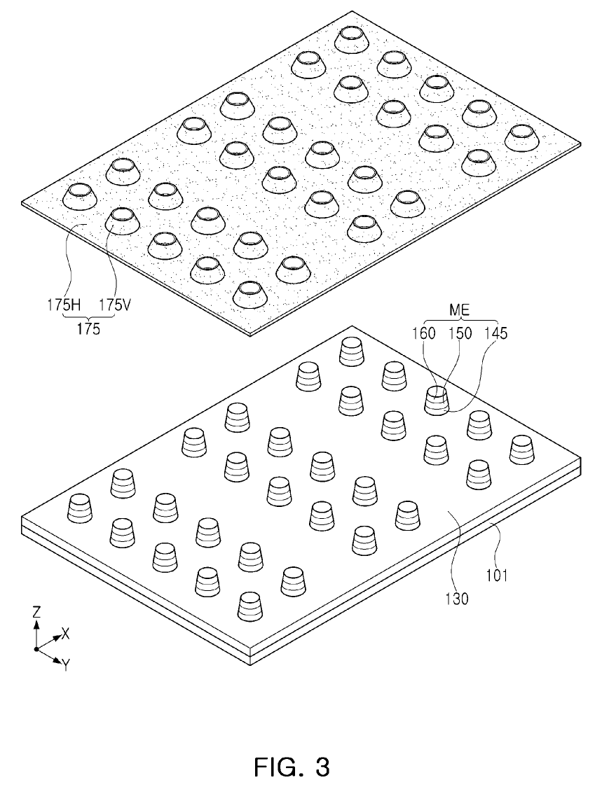

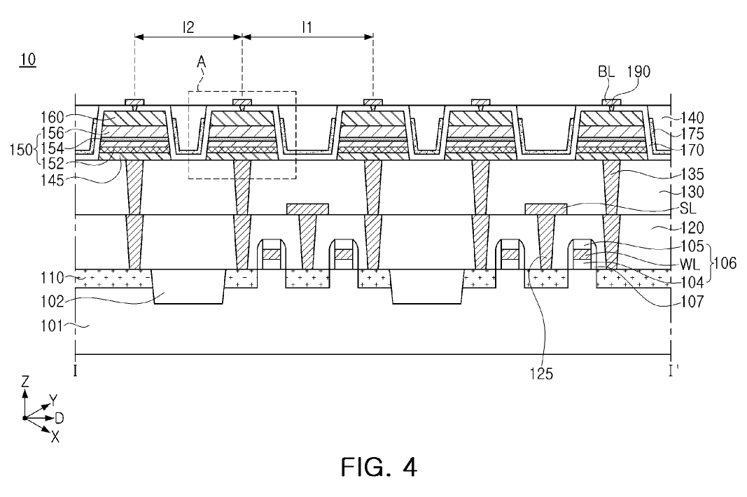

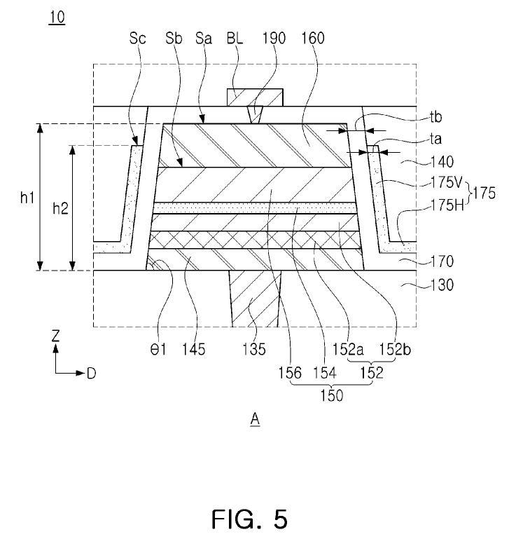

FIG. 2 is a plan view of a magnetic memory device according to an example embodiment of the present disclosure. FIG. 3 is an exploded perspective view of a magnetic memory device according to an example embodiment of the present disclosure. FIG. 4 is a cross-sectional view of a magnetic memory device according to example embodiment of the present disclosure, which is a view illustrating a cross-section taken along a line I-I’ of FIG. 2. FIG. 5 is an enlarged view of a portion of the magnetic memory device of FIG. 4.

Referring to FIG. 2, FIG. 3, FIG. 4 and FIG. 5, element isolation patterns (e.g., a device isolation film 102) defining active patterns ACT may be formed on a substrate 101. The substrate 101 may be a silicon substrate, a germanium substrate, and/or a silicon-germanium substrate.

The active patterns ACT may be arranged two-dimensionally along a plurality of rows and a plurality of columns, and each of the active patterns ACT may be a rectangle (or bar shape) extending in a diagonal direction (D-direction) with respect to an X-direction and a Y-direction, which may be perpendicular to each other. The active patterns ACT may be arranged in the diagonal direction (D-direction) to form each row, and may be arranged in a direction, perpendicular to the diagonal direction, to form each column. The active patterns ACT may be doped with a first conductivity-type dopant.

A gate 106 forming a word line WL may be disposed on the substrate 101. The gate 106 includes a gate insulating layer pattern (e.g., a gate insulating layer 104), a word line WL, and a gate mask layer 105, which may be sequentially stacked. Meanwhile, a spacer 107 may be disposed on a sidewall of the gate 106.

Impurity regions 110 may be formed in a region adjacent to the gate 106 on the substrate 101.

A first interlayer insulating layer 120 may be disposed on an entire surface (e.g., upper surface) of the substrate 101. Contact plugs 125 may penetrate through the first interlayer insulating layer 120. The contact plug 125 may be electrically connected to impurity regions 110 on one side of the contact plug 125, and be electrically connected to impurity regions 110 on an opposite side of the contact plug 125.

The contact plugs 125 may include at least one from among a semiconductor material doped with a dopant (e.g., doped silicon), a metal (e.g., tungsten, aluminum, titanium, and/or tantalum), a conductive metal nitride (e.g., titanium nitride, tantalum nitride, and/or tungsten nitride), and a metal-semiconductor compound (e.g., a metal silicide).

Source lines SL extending in the X-direction may be disposed on the first interlayer insulating layer 120. The source lines SL may be disposed across the word lines WL. The source lines SL may be connected to the contact plugs 125 arranged in the X-direction.

A second interlayer insulating layer 130 may be disposed on the first interlayer insulating layer 120, and the second interlayer insulating layer 130 may cover the contact plugs 125 and the source lines SL.

Lower contacts 135 may be disposed to penetrate through the second interlayer insulating layer 130, and each lower contact 135 may be electrically connected to a contact plug 125. In an example embodiment, the lower contacts 135 may be arranged to be spaced apart from each other in the X-direction and the Y-direction in a plane view. The lower contacts 135 may also be arranged in a zigzag shape in a plane view.

A plurality of magnetic memory elements ME may be disposed on the second interlayer insulating layer 130.

The plurality of magnetic memory elements ME may be disposed on the second interlayer insulating layer 130 to be in electrical contact with the lower contacts 135, and may be disposed to have a predetermined separation distance on an X-Y plane.

The plurality of magnetic memory elements ME may be disposed to form a matrix, but embodiments of the present disclosure are not limited thereto, and may be disposed in a zigzag shape. In addition, the separation distance between the plurality of memory elements ME may be different from each other. For example, a first separation distance I1 between two magnetic memory elements ME disposed in the diagonal direction (D-direction) on one active region (e.g., impurity region 110) may be greater than a second separation distance I2 between magnetic memory elements ME on an adjacent active region (e.g., impurity region 110).

Each of the magnetic memory elements ME may have a circular, elliptical, or polygonal shape (e.g., a rectangular shape) on an X-Y plane, and when viewed in a cross-section thereof in a vertical direction (e.g., Z-direction), a width of the upper surface of the magnetic memory element ME may be equal to or smaller than a width of the lower surface of the magnetic memory element ME, and when there is a difference in the widths of the upper surface and the lower surface, a side surface of the magnetic memory element ME between the upper surface and the lower surface may have an inclination θ1. The inclination θ1 of the side surface with respect to the lower surface may be less than or equal to 90 degrees, but may be greater than 70 degrees. Therefore, each of the magnetic memory elements ME may be formed as a pillar-shaped stacked structure on the second interlayer insulating layer 130.

Each of the magnetic memory elements ME may include a lower electrode 145, an upper electrode 160, and a magnetic tunnel junction pattern 150 between the lower electrode 145 and the upper electrode 160.

A lower electrode 145 may be disposed on the lower contacts 135. The lower electrode 145 may include a conductive material such as titanium, tantalum, ruthenium, titanium nitride, tantalum nitride, or tungsten. The conductive material may be used alone or in combination thereof. For example, the lower electrode 145 may have a double film structure such as ruthenium/titanium, ruthenium/tantalum, ruthenium/titanium nitride, ruthenium/tantalum nitride, titanium nitride/tungsten, or the like.

A magnetic tunnel junction pattern 150 may be disposed on the lower electrode 145. The magnetic tunnel junction pattern 150 may include a lower magnetic layer 152, a tunnel barrier layer 154 and an upper magnetic layer 156, sequentially disposed on the lower magnetic layer 152.

At least a portion of the lower electrode 145 may be patterned simultaneously with the magnetic tunnel junction pattern 150.

In the present embodiment, a vertical magnetization-type magnetic tunnel junction device in which the lower magnetic layer 152 functions as a pinned layer and the upper magnetic layer 156 functions as a free layer is described as an example. However, a vertical magnetization-type magnetic tunnel junction device in which the lower magnetic layer 152 functions as a free layer and the upper magnetic layer 156 functions as a pinned layer may be formed. In addition, the first lower magnetic layer 152a may have a fixed magnetization direction.

The lower magnetic layer 152 may include a first lower magnetic layer 152a and a second lower magnetic layer 152b on the first lower magnetic layer 152a. The first lower magnetic layer 152a may include a ferromagnetic material layer. The ferromagnetic material layer may include, for example, cobalt (Co), iron (Fe), nickel (Ni), platinum (Pt), palladium (Pd), and the like.

The second lower magnetic layer 152b on the first lower magnetic layer 152a may include a ferromagnetic material layer. The ferromagnetic material layer may have a magnetization direction thereof determined by an anti-ferromagnetic material layer. For example, the ferromagnetic material layer may include cobalt (Co), iron (Fe), nickel (Ni), platinum (Pt), palladium (Pd), or the like, and may have a synthetic anti-ferromagnet (SAF) structure. The SAF structure may be a multilayer film structure in which a plurality of magnetic layers and at least one intermediate layer are sequentially stacked. For example, the SAF structure may be a multilayer film structure in which a first magnetic layer, an intermediate layer, and a second magnetic layer are sequentially stacked. The SAF structure may be a multilayer film structure in which a first magnetic layer, a first intermediate layer, a second magnetic layer, a second intermediate layer, and a third magnetic layer are sequentially stacked. For example, the first magnetic layer may include a Fe-Pt alloy, a Fe-Pd alloy, a Co-Pd alloy, a Co-Pt alloy, a Fe-Ni-Pt alloy, a Co-Fe-Pt alloy, a Co-Ni-Pt alloy, a Ni-Fe alloy, a Co-Fe alloy, a Ni-Fe-B alloy, a Co-Fe-B alloy, a Ni-Fe-Si-B alloy, a Co-Fe-Si-B, or the like. The second and third magnetic layers may include a single film of cobalt (Co), iron (Fe), platinum (Pt), palladium (Pd), or multiple films thereof, and the intermediate layer may include ruthenium (Ru), tantalum ta, chromium (Cr), copper (Cu), or the like.

A tunnel barrier layer 154 may be disposed on the lower magnetic layer 152. The tunnel barrier layer 154 may include any one selected from among magnesium oxide (MgO), aluminum oxide (Al₂O₃), silicon oxide (SiO₂), and boron oxide (B₂O₃). For example, the tunnel barrier layer 154 may include aluminum oxide (Al₂O₃).

An upper magnetic layer 156 may be disposed on the tunnel barrier layer 154. The upper magnetic layer 156 may be a free magnetic layer, may include the same material as a material of the second lower magnetic layer 152b, and may be magnetized in the same direction as the second lower magnetic layer 152b. That is, the upper magnetic layer 156 may have the same magnetization direction as the second lower magnetic layer 152b. The upper magnetic layer 156 may include at least one from among cobalt (Co), iron (Fe), nickel (Ni), palladium (Pd), and platinum (Pt). For example, the upper magnetic layer 156 may include an Fe-Pt alloy, an Fe-Pd alloy, a Co-Pd alloy, a Co-Pt alloy, an Fe-Ni-Pt alloy, a Co-Fe-Pt alloy, a Co-Ni-Pt alloy, and the like. The upper magnetic layer 156 and the second lower magnetic layer 152b may include materials having a great remanence, and may be materials having a greater remanence than a remanence of a shielding structure 175.

An upper electrode 160 may be disposed on the magnetic tunnel junction pattern 150. The upper electrode 160 may have a thickness greater than a thickness of the lower electrode 145, and may include a single layer or multiple layers of a conductive material such as titanium, tantalum, ruthenium, titanium nitride, tantalum nitride, tungsten, or the like.

A bit line BL may be formed as a metal wiring disposed on a magnetic tunnel junction pattern 150 and contacting (e.g., directly contacting) an upper electrode 160. The bit line BL may be formed of a metal having low resistivity such as, for example, copper (Cu). An upper portion of the bit line BL may have a width that is greater than a width of a lower portion of the bit line BL.

A first insulating layer 170 covering all side surfaces of the magnetic tunnel junction pattern 150 and a side surface and an upper surface of the upper electrode 160 may be disposed on the second interlayer insulating layer 130. An upper surface Sa of the upper electrode 160 may be disposed at a level lower than a level of the upper surface (e.g., uppermost surface) of the first insulating layer 170. That is, the first insulating layer 170 may be disposed to cover the upper surface of the second interlayer insulating layer 130, parallel to the upper surface of the substrate 101, and all of the side surfaces and the upper surface of the magnetic memory element ME. A first insulating layer 170 may be disposed on the side surface and the upper surface of the magnetic memory element ME to have a first thickness tb, and may be conformally arranged along an outer periphery of the magnetic memory element ME. The first insulating layer 170 may include an insulating material having etch selectivity with respect to the third interlayer insulating layer 140, and may include, for example, silicon nitride.

A shielding structure 175 may be disposed on the first insulating layer 170.

The shielding structure 175 may include a magnetic material, a plate portion 175H extending in a horizontal direction on the second interlayer insulating layer 130, parallel to the upper surface of the substrate 101, and protrusions 175V which are bent upwardly from the plate portion 175H and protrude to surround at least a portion of the side surface of each of the magnetic memory elements ME. The shielding structure 175 may be disposed to have a bent portion (e.g., a corner) between the plate portion 175H and the protrusions 175V.

As illustrated in FIG. 3, the plate portion 175H and the protrusions 175V may extend together as a single metal layer, and a thickness of the plate portion 175H and a second thickness ta of the protrusions 175V may be substantially the same as each other. The plate portion 175H and the protrusions 175V may be defined as an integrated structure. The second thickness ta of the shielding structure 175 may be smaller than the first thickness tb of the first insulating layer 170. For example, the second thickness ta of the shielding structure 175 may be 1/4 to 1/8 of the first thickness tb of the first insulating layer 170.

Since the shielding structure 175 may be uniformly formed to have a second thickness ta, a bulk-type shielding structure may not be disposed in a separation space between the magnetic memory elements ME, so that signal delay (RC delay) can be minimized.

A plate portion 175H may extend parallel to the upper surface of the substrate 101 on the second interlayer insulating layer 130, and may be arranged in a separation space between a plurality of magnetic memory elements ME which are disposed to be spaced apart from each other. Protrusions 175V which are penetrated by respective magnetic memory elements ME and surround side surfaces of the magnetic memory element ME may be disposed. Accordingly, the disposition of the protrusions 175V on the plate portion 175H may be the same as the disposition of the magnetic memory elements ME.

The protrusions 175V may surround the side surface of the magnetic memory element ME on the first insulating layer 170, and may include an inner surface in contact with an outer surface of the first insulating layer 170, an outer surface opposite of the inner surface, and an upper surface Sc having a length equal to the second thickness ta between the inner surface and the outer surface. When a second height h2 of the protrusions 175V is defined as a vertical length from an upper surface of the second interlayer insulating layer 130 to the upper surface Sc of the protrusions 175V, a first height h1 of the magnetic memory element ME may be defined as a length from the upper surface of the second interlayer insulating layer 130 to an upper surface Sa of the upper electrode 160.

The first height h1 may be greater than the second height h2, and accordingly, the upper surface Sc of the protrusions 175V may be located at a level lower than a level of the upper surface of the magnetic memory element ME (e.g., the upper surface Sa of the upper electrode 160).

The upper surfaces Sc of the protrusions 175V may be located at substantially the same level as each other, and the upper surfaces Sc of the protrusions 175V may be located on a level higher than a level of the magnetic tunnel junction pattern 150.

Specifically, the upper surfaces Sc of the protrusions 175V may overlap with the upper electrode 160 in a horizontal direction, and may be located between the upper surface Sa and a lower surface (e.g., a surface in contact with an upper surface Sb) of the upper electrode 160. The upper surfaces of the protrusions 175V may be located at a level higher than a level of the upper surface Sb of the magnetic tunnel junction pattern 150 (e.g., the upper surface Sb of the upper magnetic layer 156). Lower ends of the protrusions 175V may be located at a level lower than a level of a lower end of the magnetic tunnel junction pattern 150, (e.g., the lower surface of the first lower magnetic layer 152a).

Accordingly, the protrusions 175V may overlap with the magnetic tunnel junction pattern 150 in a horizontal direction to completely surround the side surface of the magnetic tunnel junction pattern 150, thereby shielding a magnetic field to be injected into the magnetic tunnel junction pattern 150. Each protrusion 175V may have a shape similar to a magnetic memory element ME, and when a cross-section of the magnetic memory element ME is circular, elliptical, or polygonal, horizontal cross-sections of the protrusions 175V can have a circular, elliptical or polygonal frame shape.

The shielding structure 175 may include a magnetic material such as, for example, a weak magnetic material. The weak magnetic material may include a material having lower remanence than a remanence of the lower magnetic layer 152 or the upper magnetic layer 156.

A weak magnetic material may include cobalt (Co), may be formed of only cobalt, or may include cobalt-zirconium-tantalum, but an example embodiment thereof is not limited thereto.

When the shielding structure 175 includes cobalt (Co), the lower magnetic layer 152 or the upper magnetic layer 156 may include a material having a greater remanence than cobalt (Co).

As described above, the shielding structure 175 may be disposed on the side surface of the magnetic tunnel junction pattern 150 to cover the entire magnetic tunnel junction pattern 150 from its upper end to its lower end, so that a vertical external magnetic field injected from the outside may be adsorbed. Therefore, since an external magnetic field may not be injected into the magnetic tunnel junction pattern 150 that is internal, the magnetism stored in the magnetic tunnel junction pattern 150 may be maintained.

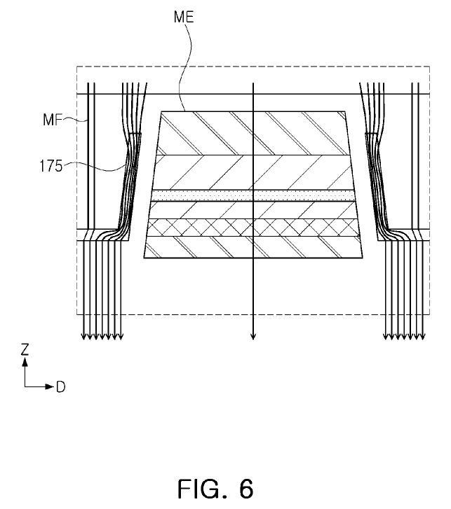

In addition, as illustrated in FIG. 6, an external magnetic field injected horizontally by the plate portion 175H may not be injected into the magnetic tunnel junction pattern 150, thereby protecting the magnetic tunnel junction pattern 150.

As described above, when a shielding structure 175 is formed integrally over the entire surface (e.g., entire side surface) of a magnetic memory device 10, the first insulating layer 170 on the upper surface Sa of the upper electrode 160, which is an upper end of each magnetic memory element ME, and the first insulating layer 170 on the side surface of the upper electrode 160 may be partially opened.

A third interlayer insulating layer 140 may be disposed on the shielding structure 175. The third interlayer insulating layer 140 may include the same material as a material of the first interlayer insulating layer 120 and the second interlayer insulating layer 130, and may have a multilayer stacked structure. The upper surface of the third interlayer insulating layer 140 may be coplanar with the upper surface of the first insulating layer 170, but an example embodiment thereof is not limited thereto.

Upper vias 190 penetrating through the upper surface of the first insulating layer 170 may be disposed, and bit lines BL, connected to the upper vias 190, may be disposed on the first insulating layer 170 as wiring structures.

The first interlayer insulating layer 120, the second interlayer insulating layer 130, and the third interlayer insulating layer 140 may include materials which are not removed by an ashing process. The first interlayer insulating layer 120, the second interlayer insulating layer 130, and the third interlayer insulating layer 140 may include at least one from among, for example, boro-phospho-silicate glass (BPSG), tonen silazene (TOSZ), undoped silicate glass (USG), spin-on glass (SOG), flowable oxide (FOX), tetraethyl orthosilicate (TEOS), and high density plasma chemical vapor deposition (HDP-CVD) oxide.

FIG. 6 illustrates an external magnetic field flowing around a magnetic memory device including the shielding structure 175 of FIG. 2, FIG. 3, FIG. 4, and FIG. 5.

An external magnetic field MF may penetrate through the magnetic memory element ME in various directions, and a vertical portion of the external magnetic field MF flowing in the Z-direction and a horizontal portion of the external magnetic field MF in a direction, perpendicular to the Z-direction, may flow through the magnetic memory element ME.

In this case, the portion of the external magnetic field MF flowing in the horizontal direction may be completely shielded by the plate portion 175H of the shielding structure 175 and may not penetrate into the magnetic memory element ME.

In addition, the portion of the external magnetic field MF flowing in the vertical direction may be diverted into the protrusion 175V and flow to be concentrated in the protrusion 175V, so that the portion of the external magnetic field MF flowing in the vertical direction may not flow into the magnetic memory element ME, thereby shielding the influence of the external magnetic field MF on the internal magnetic memory element ME. In addition, since the shielding structure 175 may include a weaker magnetic material (e.g., a material having lower remanence than a remanence of the magnetic materials of the magnetic tunnel junction patterns 150 of the magnetic memory element ME) so that when the external magnetic field MF is removed, it loses the magnetism again and does not affect the magnetic memory element ME therein.

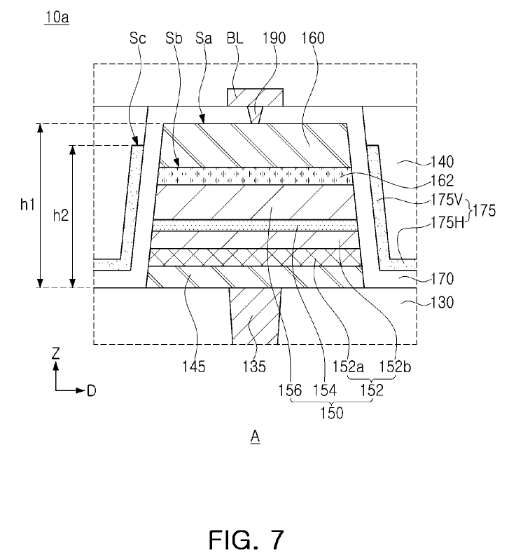

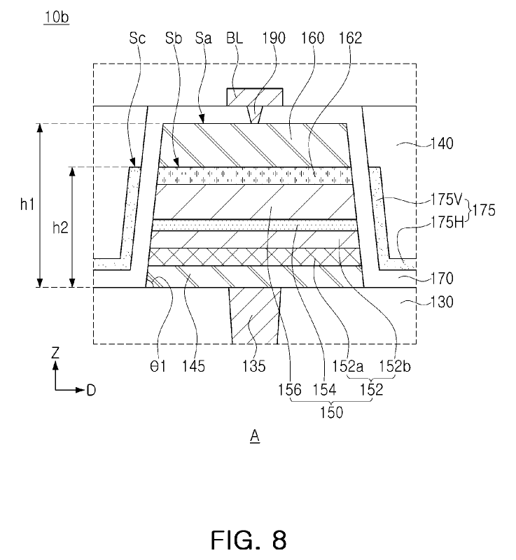

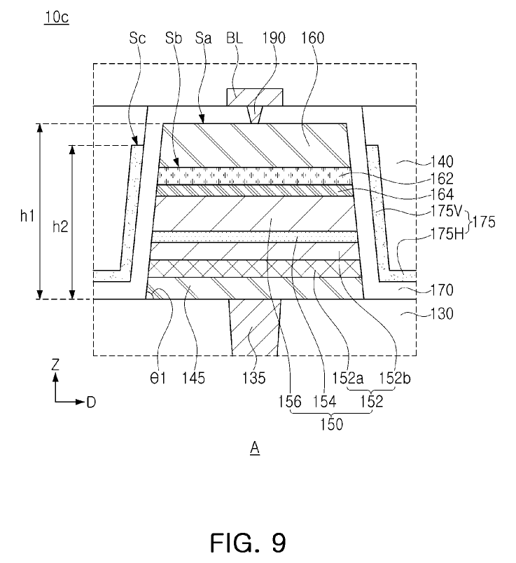

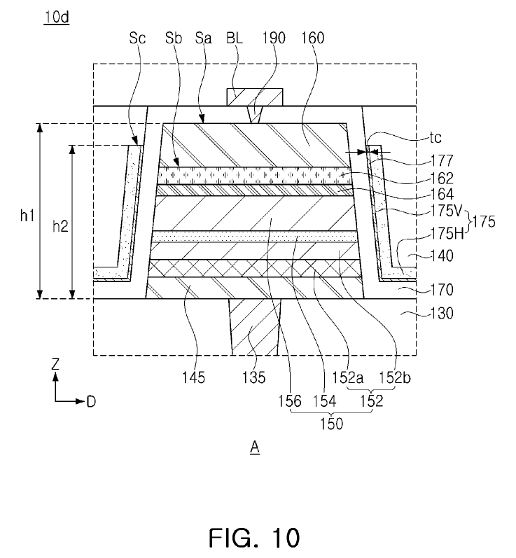

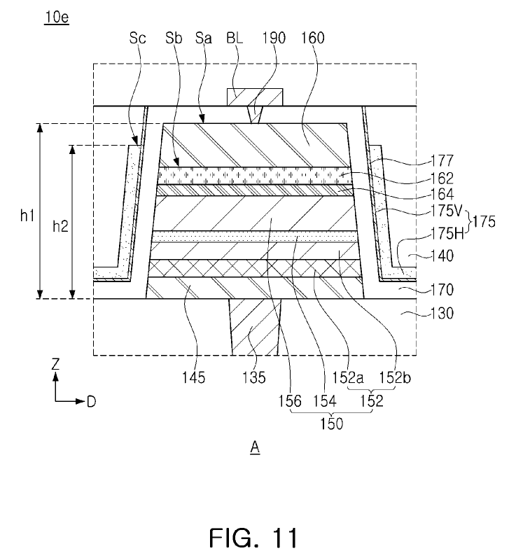

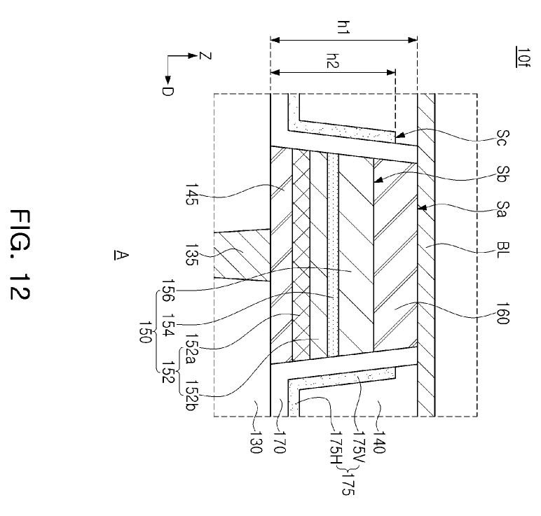

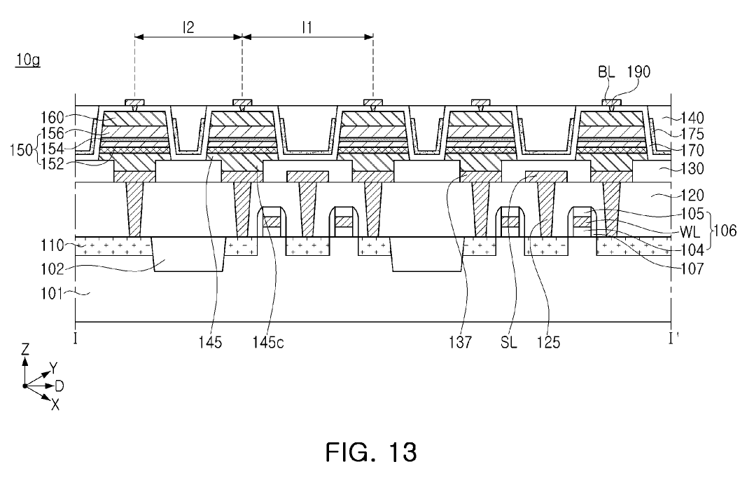

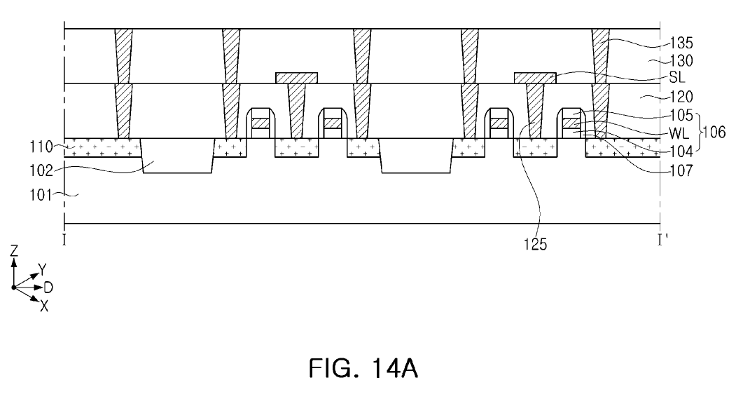

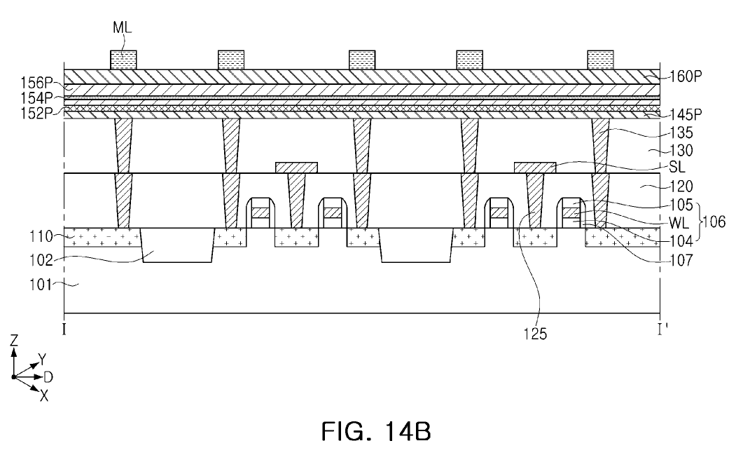

Hereinafter, another magnetic memory device according to another embodiment of the present disclosure will be described with reference to FIG. 7, FIG. 8, FIG. 9, FIG. 10, FIG. 11, and FIG. 12.

FIG. 7, FIG. 8, FIG. 9, FIG. 10, FIG. 11, and FIG. 12 illustrate magnetic memory devices corresponding to FIG. 5.

A magnetic memory element ME of a magnetic memory device 10a of FIG. 7 may be the same as the magnetic memory device 10 of FIG. 5, except for further including a capping layer 162 on a magnetic tunnel junction pattern 150.

The magnetic memory element ME of FIG. 7 may include a capping layer 162 between a magnetic tunnel junction pattern 150 and an upper electrode 160, and the capping layer 162 may include a conductive material and may include a different material from a material of the upper electrode 160. For example, when the upper electrode 160 includes tungsten (W), the capping layer 162 may include titanium nitride (TiN) or tantalum nitride (TaN).

The capping layer 162 may have a thickness smaller than a thickness of the upper electrode 160, and a side surface of the capping layer 162 may have an inclination that is continuous with respect to the lower magnetic layer 152, the upper magnetic layer 156, and the upper electrode 160.

A first insulating layer 170 may surround the magnetic memory device ME, and a shielding structure 175 may be on the first insulating layer 170, which may be the same as in FIG. 2, FIG. 3, FIG. 4, and FIG. 5.

In this case, upper surfaces Sc of the protrusions 175V of the shielding structure 175 may be located at a higher level than a level of an upper surface Sb of the capping layer 162, and may overlap with the side surface of the upper electrode 160 horizontally. Therefore, the shielding structure 175 may completely shield the magnetic tunnel junction pattern 150.

A magnetic memory element ME of a magnetic memory device 10b of FIG. 8 may be the same as the magnetic memory device 10a of FIG. 7, except that the upper surface Sc of the protrusions 175V of the shielding structure 175 may be located at the same level as a level of the upper surface Sb of the capping layer 162.

When the magnetic memory element ME of FIG. 8 includes a capping layer 162 between the magnetic tunnel junction pattern 150 and the upper electrode 160, the protrusions 175V of the shielding structure 175 may have upper surfaces Sc located on substantially the same level as the level of the upper surface Sb of the capping layer 162. Therefore, the shielding structure 175 may completely shield the magnetic tunnel junction pattern 150.

A magnetic memory element ME of the magnetic memory device 10c of FIG. 9 may be the same as the magnetic memory device 10 of FIG. 5, except that the magnetic memory element ME further includes a capping layer 162 and an upper insulating layer 164 on the magnetic tunnel junction pattern 150.

The magnetic memory element ME of FIG. 9 may include a capping layer 162 between the magnetic tunnel junction pattern 150 and the upper electrode 160, and the capping layer 162 may include a conductive material, and may include a different material from a material of the upper electrode 160. For example, when the upper electrode 160 includes tungsten, the capping layer 162 may include titanium nitride or tantalum nitride.

An upper insulating layer 164 may be further disposed between the capping layer 162 and the magnetic tunnel junction pattern 150, and the upper insulating layer 164 may include the same material as a material of the tunnel barrier layer 154. For example, the upper insulating layer 164 may include hafnium oxide, but an example embodiment thereof is not limited thereto.

As described above, by disposing a separate tunneling layer between the upper electrode 160 and the magnetic tunnel junction pattern 150, a memory function may be improved.

The upper insulating layer 164 may include substantially the same material and the same thickness as a material and thickness of the tunnel barrier layer 154, but an example embodiment thereof is not limited thereto, and may include an oxide or nitride having a high dielectric constant.

The capping layer 162 and the upper insulating layer 164 may have a side surface continuously having an inclination θ1 with respect to the lower magnetic layer 152, the upper magnetic layer 156, and the upper electrode 160.

Even in this case, the protrusion 175V of the shielding structure 175 may be disposed to cover a side surface of the upper insulating layer 164, cover a side surface of the capping layer 162, and may be disposed so that the upper surface Sc of the protrusion 175V overlaps the side surface of the upper electrode 160, horizontally.

Therefore, the shielding structure 175 may completely shield the magnetic tunnel junction pattern 150.

A magnetic memory element ME of the magnetic memory device 10d of FIG. 10 may be the same as the magnetic memory device 10a of FIG. 9, except that the magnetic memory element ME further includes a diffusion barrier 177 between the shielding structure 175 and the magnetic memory element ME.

The diffusion barrier 177 of FIG. 10 may be disposed between the shielding structure 175 and the first insulating layer 170.

The diffusion barrier 177 may have the same shape as a shape of the shielding structure 175, and may be disposed along the plate portion 175H and the protrusion 175V of the shielding structure 175. The diffusion barrier 177 may have a third thickness tc, smaller than the second thickness of the shielding structure 175, and the third thickness tc may be, for example, 10 Å to 20 Å. The diffusion barrier 177 may include a material different from a material of the shielding structure 175, and may include, for example, titanium nitride or tantalum nitride.

A portion of the diffusion barrier 177 on the protrusion 175V of the shielding structure 175 may have an upper end located at the same level as a level of the upper end Sc of the protrusion 175V, and may overlap a side surface of the upper electrode 160 in a plane (e.g., in a horizontal direction). Therefore, the upper end of the diffusion barrier 177 may be disposed between the upper surface Sa and the lower surface (contacting the upper surface Sb) of the upper electrode 160.

A magnetic memory element ME of the magnetic memory device 10e of FIG. 11 may be the same as the magnetic memory device of FIG. 10, except for a level of an upper end of the diffusion barrier 177 between the shielding structure 175 and the magnetic memory element ME.

The diffusion barrier 177 of FIG. 11 may be disposed between the shielding structure 175 and the first insulating layer 170.

The diffusion barrier 177 may have the same shape as a shape of the shielding structure 175, and may be disposed along the plate portion 175H and the protrusion of the shielding structure 175. The diffusion barrier 177 may have a third thickness tc (see FIG. 10), smaller than the second thickness of the shielding structure 175. The diffusion barrier 177 may include a material different from a material of the shielding structure 175, and may include, for example, titanium nitride or tantalum nitride.

A portion of the diffusion barrier 177 on the protrusion 175V of the shielding structure 175 may have an upper end located at a level higher than a level of the upper surface Sc of the protrusion 175V. For example, the upper end of the diffusion barrier 177 may be coplanar with the upper surface of the first insulating layer 170.

A magnetic memory element ME of the magnetic memory device 10f of FIG. 12 may be the same as the magnetic memory device 10 of FIG. 5, except for an upper portion of the first insulating layer 170.

An upper surface Sa of the upper electrode 160 may be exposed from the first insulating layer 170 of FIG. 12, and the first insulating layer 170 may be disposed to surround a side surface of the magnetic memory element ME.

A bit line BL may be disposed to directly contact the exposed upper surface Sa of the upper electrode 160.

Accordingly, vias penetrating through the first insulating layer 170 between the upper electrode 160 and the bit line BL may be omitted.

When the first insulating layer 170 exposes the upper surface Sa of the upper electrode 160, a level of the upper end of the first insulating layer 170 may be greater than a height of the upper end Sc of the protrusion 175V of the shielding structure 175. Accordingly, even if the bit line BL is disposed to be in direct contact with the upper surface Sa of the upper electrode 160, it may be spaced apart in the vertical direction from the upper end Sc of the shielding structure 175. The upper end of the first insulating layer 170 may protrude above the upper end Sc of the protrusion of the shielding structure 175 to surround the entire side surface of the upper electrode 160, and the upper end of the first insulating layer 170 may be disposed on the same level as a level of the upper surface Sa of the upper electrode 160.

A magnetic memory device 10g of FIG. 13 may be the same as the magnetic memory device 10 of FIG. 4 except for the second interlayer insulating layer 130 and the lower contacts.

The magnetic memory device 10f of FIG. 13 may include upper pads 137 having the same thickness as a thickness of the source line SL on the first interlayer insulating layer 120.

The upper pads 137 may be formed by patterning the same metal layer as a metal layer of the source line SL, but an example embodiment thereof is not limited thereto.

A second interlayer insulating layer 130 may be disposed to cover the upper pads 137. The second interlayer insulating layer 130 may have a thickness smaller than a thickness of the first interlayer insulating layer 120 and the third interlayer insulating layer 140, but an example embodiment thereof is not limited thereto.

A lower electrode 145 of a magnetic memory element ME may be disposed from an upper portion of the second interlayer insulating layer 130.

When the second interlayer insulating layer 130 is etched to a predetermined depth so that upper pads 137 therebelow are exposed, the lower electrode 145 may be disposed to be in contact with the upper pads 137.

Accordingly, the lower electrode 145 may include contact protrusions 145c extending downwardly in the second interlayer insulating layer 130 and being in contact with the upper pads 137, and the lower electrode 145 (e.g., the contact protrusion 145c) may be disposed to extend in the Z-direction.

An upper portion of the lower electrode 145 and the contact protrusion 145c below the upper portion may include the same material as each other, may be integrated, and may include a bent portion (e.g., a step) due to a difference in widths between the upper portion of the lower electrode 145 and the contact protrusion 145c. For example, the width of the upper portion of the lower electrode 145 may be greater than the width of the contact protrusion 145c, but an example embodiment thereof is not limited thereto.

As described above, the thickness of the second interlayer insulating layer 130 may be minimized by forming the lower contacts in the form of pads rather than long pillar-type vias like the contact plug 125.

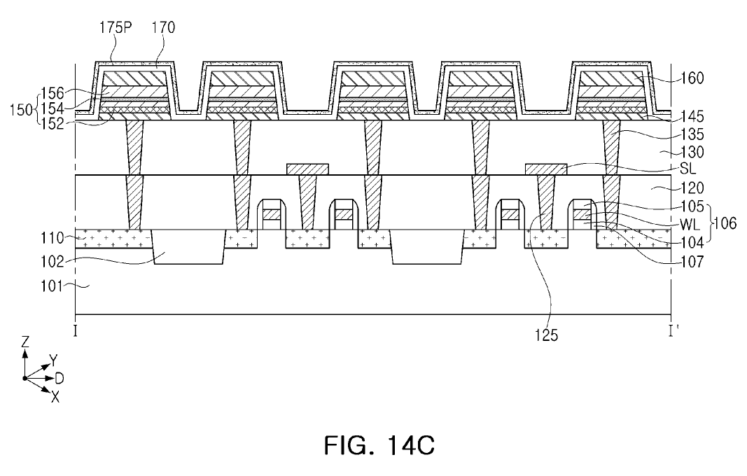

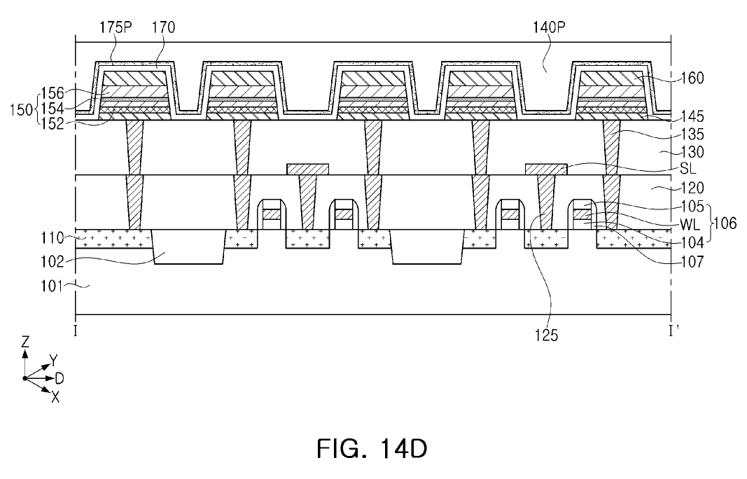

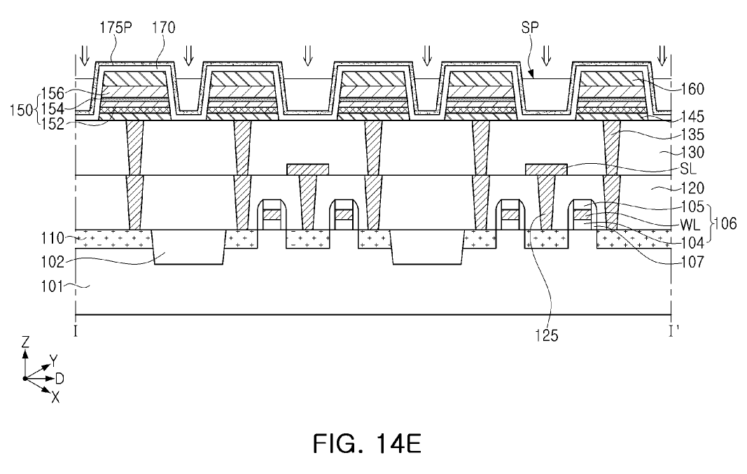

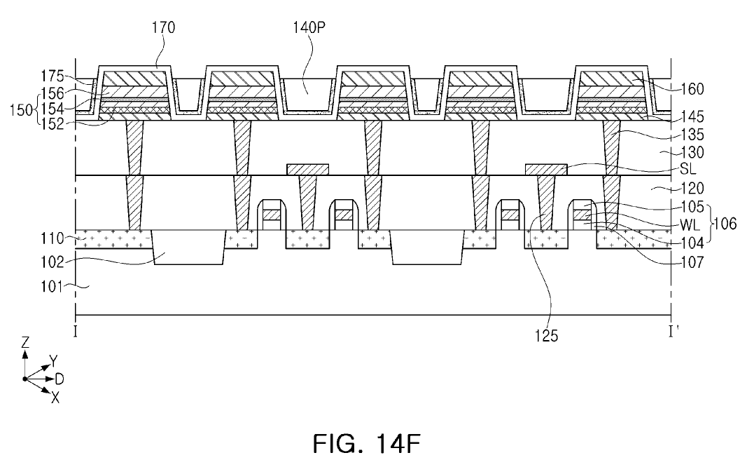

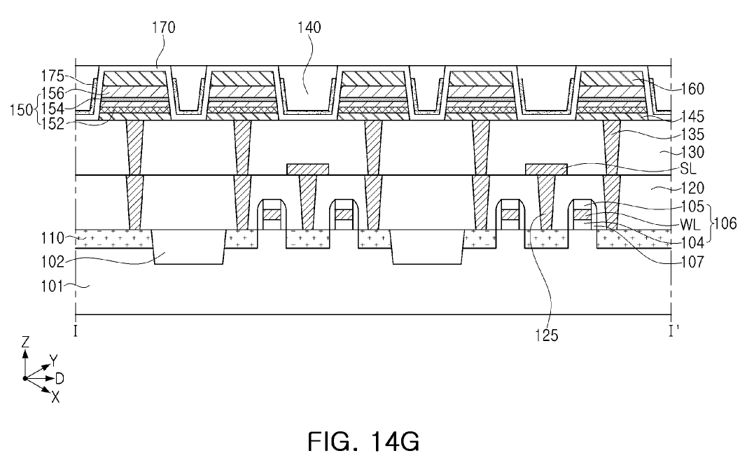

Hereinafter, a method for manufacturing the magnetic memory device of FIG. 4 will be described with reference to FIGS. 14A to 14G. FIGS. 14A to 14G illustrate cross-sections taken along the line I-I’ of FIG. 2.

Referring to FIG. 14A, a device isolation film 102 may be formed on a substrate 101. The device isolation film 102 may be formed through a shallow trench isolation (STI) process. A gate insulating layer 104, a word line WL, and a gate mask layer 105 may be sequentially disposed on the substrate 101, and by patterning the same through a photolithography process, gates 106 may be formed on the substrate 101. The gate insulating layer 104 may be formed using silicon oxide or metal oxide. The word line WL may be formed using doped polysilicon or metal. The gate mask layer 105 may be formed using silicon nitride.

Thereafter, impurity regions 110 may be formed in a region adjacent to the gates 106 through an ion implantation process using the gates 106 on the substrate 101 as an ion implantation mask. The impurity regions 110 may function as source/drain regions of a transistor comprised of the gates 106.

The gate 106 and the impurity regions 110 (e.g., a first impurity region and a second impurity region) may form a transistor. Meanwhile, spacers 107 may be formed using silicon nitride on sidewalls of the gates 106.

Thereafter, a first interlayer insulating layer 120 surrounding the gates 106 and spacers 107 may be formed on the substrate 101. The first interlayer insulating layer 120 may be partially etched to form first holes exposing the impurity regions 110.

Thereafter, a first conductive layer filling the first holes may be formed on the first interlayer insulating layer 120, and an upper portion of the first conductive layer may be removed through a chemical mechanical polishing and/or an etch-back process until the first interlayer insulating layer 120 is exposed, so that a contact plug 125 formed within the first holes is formed. Each contact plug 125 may contact the impurity regions 110, respectively. The first conductive layer may be formed using doped polysilicon, metal, or the like. The contact plug 125 may function as a contact of a source line SL.

A second conductive layer contacting the contact plug 125 may be formed on the first interlayer insulating layer 120 and patterned to form a source line SL. The second conductive layer may be formed using doped polysilicon, metal, or the like. Thereafter, a second interlayer insulating layer 130 covering the source line SL may be formed on the first interlayer insulating layer 120. The second interlayer insulating layer 130 may be partially etched to form second holes exposing the contact plug 125, and a third conductive layer filling the second holes may be formed on the contact plug 125 and the second interlayer insulating layer 130. Lower contacts 135 formed within the second holes may be formed by removing an upper portion of the third conductive layer until the second interlayer insulating layer 130 is exposed through a mechanical chemical polishing process and/or an etch back process.

Referring to FIG. 14B, a preliminary lower electrode layer 145P may be formed on the second interlayer insulating layer 130 and the lower contacts 135. The preliminary lower electrode layer 145P may be formed by an atomic layer deposition process, a chemical vapor deposition process, or the like using a conductive material such as titanium, tantalum, ruthenium, titanium nitride, tantalum nitride, or tungsten. For example, the preliminary lower electrode layer 145P may have a double layer structure of ruthenium/titanium, ruthenium/tantalum, ruthenium/titanium nitride, ruthenium/tantalum nitride, titanium nitride/tungsten, or the like.

A preliminary lower magnetic layer 152P, a preliminary tunnel barrier layer 154P, a preliminary upper magnetic layer 156P, and a preliminary upper electrode layer 160P may be sequentially formed on the preliminary lower electrode layer 145P. The preliminary lower magnetic layer 152P, the preliminary tunnel barrier layer 154P, the preliminary upper magnetic layer 156P, and the preliminary upper electrode layer 160P may be formed by a chemical vapor deposition process or an atomic layer deposition process.

A mask pattern ML may be formed on the preliminary upper electrode layer 160P to correspond to the position of the lower contacts 135. The mask pattern ML may be a photoresist pattern or a hard mask pattern including silicon oxide, silicon nitride, or the like.

Referring to FIG. 14C, a magnetic tunnel junction pattern 150 comprised of a lower magnetic layer 152, a tunnel barrier layer 154, and an upper magnetic layer 156, and an upper electrode 160 may be formed by patterning using the mask pattern ML illustrated in FIG. 14B as an etching mask. In this case, at least a portion of the lower electrode 145 may be patterned. After patterning the magnetic tunnel junction pattern 150, a first insulating layer 170 covering the lower electrode 145, the magnetic tunnel junction pattern 150, and all of side surfaces of the upper electrode 160 and an upper surfaces of the upper electrode 160 may be formed on the second interlayer insulating layer 130.

As a thickness of the upper electrode 160 becomes thinner, a distance between the bit line BL (see FIG. 4) and the upper magnetic layer 156 of the magnetic tunnel junction pattern 150 becomes closer. If the upper magnetic layer 156 is a free layer, as the distance becomes closer, the efficiency of switching the magnetization direction of the free layer during the write process increases.

The patterning may be performed by dry etching. Specifically, the patterning may be performed by a light element ion etching process or a light element ion plasma etching. The light element may be performed using, for example, at least one gas from among hydrogen (H₂), helium (He), nitrogen (N₂), argon (Ar), and neon (Ne). An upper surface of the second interlayer insulating layer 130 exposed between the magnetic tunnel junction patterns 150 may be recessed during the etching process.

Upper and lower surfaces of the patterned magnetic memory elements ME may be covered, and a first insulating layer 170 may be formed. The first insulating layer 170 may include silicon nitride, and may also include silicon oxide. The first insulating layer 170 may be deposited to a first thickness tb (see FIG. 5) and conformally deposited along the magnetic memory elements ME.

A preliminary shielding layer 175P may be formed on the first insulating layer 170 to have a second thickness ta (see FIG. 5).

The preliminary shielding layer 175P may be formed by depositing a weak magnetic material to have the second thickness ta, and may be formed to cover the entire first insulating layer 170. Therefore, it may be deposited in a plate shape on the upper surface of the second interlayer insulating layer 130, and may be formed conformally to cover the magnetic memory elements ME.

Referring to FIG. 14D, a preliminary third interlayer insulating layer 140P may be formed on the preliminary shielding layer 175P. The preliminary third interlayer insulating layer 140P may cover the entire preliminary shielding layer 175P, cover an upper end of the magnetic memory element ME, and be formed to have a sufficient thickness.

The preliminary third interlayer insulating layer 140P may be deposited to include the same material as a material of the first interlayer insulating layer 120 and the second interlayer insulating layer 130, but an example embodiment thereof is not limited thereto.

Referring to FIG. 14E, a portion of the preliminary third interlayer insulating layer 140P may be removed to expose an upper surface of the preliminary shielding layer 175P on the upper electrode 160. Removing a portion of the preliminary third interlayer insulating layer 140P may be performed by an etch-back process. In this case, a portion of an upper surface and a side surface of the preliminary shielding layer 175P covering the magnetic memory elements ME may be exposed. In this case, the etched surface SP of the preliminary third interlayer insulating layer 140P may be etched to overlap with the side surface of the upper electrode 160 in a plane (e.g., horizontal directions). For example, it may be located at level higher than a level of the upper surface of the magnetic tunnel junction pattern 150.

Referring to FIG. 14F, the preliminary shielding layer 175P exposed by the preliminary third interlayer insulating layer 140P may be etched to form a shielding structure 175.

The preliminary shielding layer 175P disposed on the upper surface of the first insulating layer 170, covering the magnetic memory element ME and a portion of the side surface bent from the upper surface, may be etched to the upper surface SP (see FIG. 14E) of the preliminary third interlayer insulating layer 140P.

In this case, the preliminary shielding layer 175P may be removed through wet etching, and in this case, an upper surface of a protrusion 175V of the shielding structure 175 may be formed to be recessed by a predetermined depth from the upper surface of the preliminary third interlayer insulating layer 140P.

Accordingly, the shielding structure 175 may be formed to include a plate portion 175H and protrusions 175V, and upper ends of the protrusions 175V may be located on a level higher than a level of the upper surface of the magnetic tunnel junction pattern 150.

Referring to FIG. 14G, an insulating material may be further deposited on the preliminary third interlayer insulating layer 140P to form a third interlayer insulating layer 140.

The third interlayer insulating layer 140 may be formed to cover the upper surface of the first insulating layer 170 and then polished until the upper surface of the first insulating layer 170 is exposed.

Referring to FIG. 4, a portion of the upper surface of the exposed first insulating layer 170 may be removed to form upper vias 190, and a metal wiring forming a bit line BL may be formed on the upper vias 190.

According to an embodiment of the present disclosure, a method of manufacturing a magnetic memory device may be provided and include: forming a lower magnetic layer, a tunnel barrier layer, and an upper magnetic layer on a substrate; forming a magnetic tunnel junction pattern by patterning the lower magnetic layer, the tunnel barrier layer, and the upper magnetic layer; forming a first insulating layer that covers the substrate and the magnetic tunnel junction pattern; and forming a shielding structure on the first insulating layer, the shielding structure including a plate region covering the substrate, and a protrusion surrounding the magnetic tunnel junction pattern.

The forming the shielding structure may include covering the first insulating layer with a preliminary shielding layer; covering the preliminary shielding layer with a preliminary interlayer insulating layer; exposing at least a portion of the preliminary shielding layer by etching a portion of the preliminary interlayer insulating layer; and forming a shielding structure by etching a portion of the preliminary shielding layer that is exposed.

The etching the portion of the preliminary interlayer insulating layer may include etching the preliminary interlayer insulating layer back to a level equal to or higher than a level of the magnetic tunnel junction pattern.

The etching the portion of the preliminary shielding layer that is exposed may include wet etching.

The shielding structure may include a plate portion in a separation space between the plurality of magnetic memory elements on the substrate; and protrusions protruding from the plate portion, and surrounding the magnetic tunnel junction pattern.

The plate portion may include a first thickness, the protrusions may include a second thickness, wherein the first thickness may be the same as the second thickness.

A magnetic material of the plate portion may be the same as a magnetic material of the protrusions.

The method of manufacturing the magnetic memory device may further include forming, by patterning, a lower electrode and an upper electrode. The lower electrode may be on the substrate, below the magnetic tunnel junction pattern, and the upper electrode may be on the magnetic tunnel junction pattern.

An upper surface of each of the protrusions may be etched to overlap with the upper electrode in horizontal directions.

The shielding structure may include a material having a lower remanence than a remanence of the upper magnetic layer.

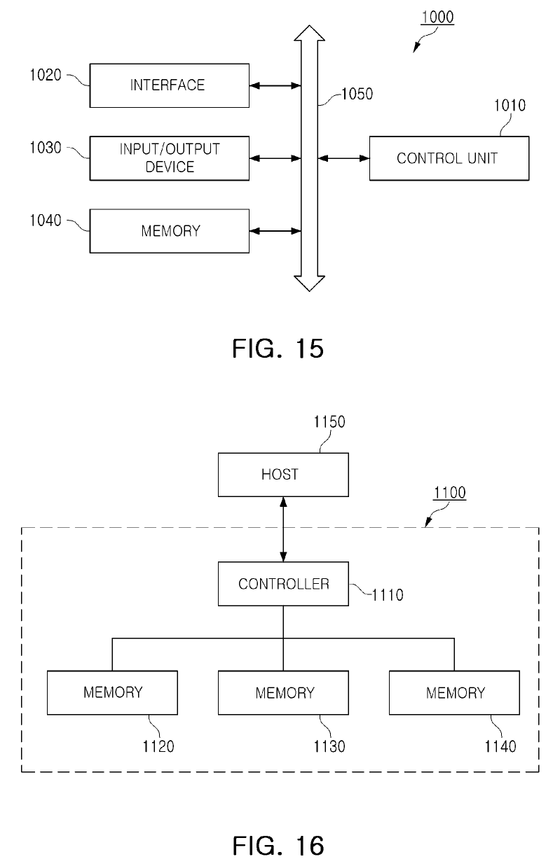

FIG. 15 and FIG. 16 are block diagrams illustrating an electronic device including a magnetic memory device according to an example embodiment of the present disclosure.

FIG. 15 illustrates an electronic device 1000 including a magnetic memory device according to an example embodiment of the present disclosure.

Referring to FIG. 15, the electronic device 1000 according to the present embodiment may include a control unit 1010 (e.g., a controller), an interface 1020, an input/output device 1030, a memory 1040, and the like. The control unit 1010, the interface 1020, the input/output device 1030, the memory 1040, and the like may be connected through a bus 1050 that provides a path through which data is transmitted.

The control unit 1010 may include at least one microprocessor, a digital signal processor, a microcontroller, and the like. The memory 1040 may include elements capable of reading and writing data in various manners, and the control unit 1010 and the memory 1040 may include any one of the various embodiments of the magnetic memory devices described above with reference to FIGS. 1 - 13.

The input/output device 1030 may include a keypad, a keyboard, a touchscreen device, a display device, an audio input/output module, and the like. The interface 1020 may be a module for transmitting and receiving data to a communication network, and may include an antenna, a wired or wireless transceiver, and the like. In addition, in addition to the components illustrated in FIG. 15, the electronic device 1000 may further include an application chipset, an image capture device, and the like. The category of the electronic device 1000 illustrated in FIG. 15 is not limited, and may be various devices such as a personal digital assistant (PDA), a portable computer, a mobile phone, a wireless phone, a laptop computer, a memory card, a portable media player, a tablet PC, and the like.

FIG. 16 is a block diagram illustrating a storage device 1100 including a magnetic memory device according to an example embodiment of the present disclosure.

Referring to FIG. 16, a storage device 1100 according to an example embodiment may include a controller 1110 communicating with a host 1150, and memories 1120, 1130, and 1140 storing data. The controller 1110 and each of the memories 1120, 1130, and 1140 may include magnetic memory elements according to various example embodiments of the present disclosure as described above with reference to FIGS. 1 - 13.

The host 1150 communicating with the controller 1110 may be various electronic devices mounted on a storage device 1100, such as a smart phone, a digital camera, a desktop, a laptop, a media player, and the like. The controller 1110 may receive a data write or read request transmitted from the host 1150 and generate a command (CMD) to store data in the memories 1120, 1130, and 1140 or to retrieve data from the memories 1120, 1130, and 1170.

As illustrated in FIG. 16, one or more memories 1120, 1130, and 1140 within a storage device 1100 may be connected in parallel to a controller 1110. By connecting a plurality of memories 1120, 1130, and 1140 in parallel to the controller 1110, a storage device 1100 having a large capacity may be implemented.

According to some embodiments of the present disclosure, a magnetic memory device may shield both external magnetic fields in a vertical direction and a horizontal direction, by forming a shielding structure integrally to cover a side surface of the magnetic memory element, and an upper surface of a substrate.

In addition, by including a material having a lower remanence than a remanence of a magnetic material in a magnetic tunnel junction pattern that is a shielding structure, the influence of the shielding structure on the magnetic memory element may be minimized.

When forming a shielding structure as an integrated structure including horizontal and vertical portions, the horizontal portion may be formed to have a thin thickness, like the vertical portion, thereby minimizing signal delay caused by a thick shielding structure. The various advantages and effects of embodiments of the present disclosure are not limited to the above description, and other various advantages and effects of embodiments of the present disclosure be more easily understood in the course of describing example embodiments of the present disclosure. While example embodiments have been shown and described above, it will be apparent to those skilled in the art that modifications and variations could be made without departing from the spirit and scope of the present disclosure.

What is claimed is:

1. A magnetic memory device, comprising:
a substrate;
magnetic memory elements spaced apart from each other on the substrate, the magnetic memory elements comprising a magnetic tunnel junction pattern; and
a shielding structure surrounding the magnetic memory elements in horizontal directions,
wherein the shielding structure comprises:
a plate portion between the magnetic memory elements; and
a protrusion protruding from the plate portion, and surrounding a magnetic memory element from among the magnetic memory elements in the horizontal directions.

2. The magnetic memory device of claim 1, wherein the plate portion comprises a first thickness,
wherein the protrusion is on a side surface of the magnetic memory element, and the protrusion comprises a second thickness,
wherein the first thickness is the same as the second thickness.

3. The magnetic memory device of claim 1, wherein the plate portion extends in the horizontal directions, and the protrusion extends from the plate portion in a vertical direction that crosses the horizontal directions.

4. The magnetic memory device of claim 1, wherein an upper surface of the magnetic memory element is exposed from the protrusion.

5. The magnetic memory device of claim 1, wherein the plate portion comprises a magnetic material, and the protrusion comprises a magnetic material that is the same as the magnetic material of the plate portion.

6. The magnetic memory device of claim 1, wherein the magnetic memory element further comprises:
a lower electrode on the substrate, wherein the magnetic tunnel junction pattern of the magnetic memory element is on the lower electrode; and
an upper electrode on the magnetic tunnel junction pattern of the magnetic memory element,
wherein the magnetic tunnel junction pattern of the magnetic memory element comprises a lower magnetic layer, a tunnel barrier layer, and an upper magnetic layer
.

7. The magnetic memory device of claim 6, wherein the protrusion comprises:
an inner surface facing the magnetic memory element;
an outer surface opposite of the inner surface; and
an upper surface between the inner surface and the outer surface.
wherein the upper surface of the protrusion horizontally overlaps with the upper electrode.

8. The magnetic memory device of claim 7, wherein a level of the upper surface of the protrusion is the same as a level of a lower surface of the upper electrode.

9. The magnetic memory device of claim 6, wherein the shielding structure comprises a material having a lower remanence than a remanence of the upper magnetic layer.

10. The magnetic memory device of claim 1, wherein the shielding structure comprises cobalt.

11. The magnetic memory device of claim 1, wherein the magnetic memory device further comprises a first insulating layer between the shielding structure and the magnetic memory elements.

12. The magnetic memory device of claim 11, wherein the magnetic memory device further comprises a diffusion barrier between the shielding structure and the first insulating layer.

13. The magnetic memory device of claim 12, wherein a level of an upper end of the diffusion barrier is the same as a level of an upper surface of the protrusion of the shielding structure.

14. The magnetic memory device of claim 12, wherein a level of an upper end of the diffusion barrier is higher than a level of an upper surface of the protrusion of the shielding structure.

15. A magnetic memory device, comprising:
a substrate;
selection elements on the substrate;
a lower interlayer insulating layer on the selection elements;
magnetic memory elements spaced apart from each other on the lower interlayer insulating layer, connected to the selection elements, and comprising a magnetic tunnel junction pattern; and
a shielding structure surrounding the magnetic memory elements in horizontal directions,
wherein the shielding structure comprises:
a plate portion extending in a first direction, from among the horizontal directions, the first direction being parallel to an upper surface of the lower interlayer insulating layer; and
a protrusion extending from the plate portion in a second direction, crossing the first direction, the protrusion surrounding a side surface of a magnetic memory element from among the magnetic memory elements in the horizontal directions.

16. The magnetic memory device of claim 15, wherein the magnetic memory element further comprises:
a lower electrode on the substrate, wherein the magnetic tunnel junction pattern of the magnetic memory element is on the lower electrode; and
an upper electrode on the magnetic tunnel junction pattern of the magnetic memory element, and
wherein the magnetic tunnel junction pattern of the magnetic memory element comprises a lower magnetic layer, a tunnel barrier layer, and an upper magnetic layer.

17. The magnetic memory device of claim 16, wherein the lower magnetic layer comprises:
a first lower magnetic layer on the lower electrode, and comprising a fixed magnetization direction; and
a second lower magnetic layer on the first lower magnetic layer, and comprising a magnetization direction that changes according to the lower electrode,
wherein a material of the second lower magnetic layer is the same as a material of the upper magnetic layer.

18. The magnetic memory device of claim 16, wherein a remanence of a material of the shielding structure is lower than a remanence of the upper magnetic layer.

19. The magnetic memory device of claim 15, wherein the protrusion of the shielding structure is on the magnetic tunnel junction pattern of the magnetic memory element.

20. A magnetic memory device, comprising:
a substrate;
selection elements on the substrate;
a lower interlayer insulating layer on the selection elements;
magnetic memory elements spaced apart from each other on the lower interlayer insulating layer, connected to the selection elements, and comprising a magnetic tunnel junction pattern;
a first insulating layer on an upper surface of the lower interlayer insulating layer and on the magnetic memory elements, the first insulating layer comprising a first thickness; and
a shielding structure extending on the first insulating layer in a first direction, and on a side surface of the magnetic memory elements in a second direction that crosses the first direction,
wherein upper surfaces of the magnetic memory elements are exposed from the shielding structure.
